(19) United States
(12) Patent Application Publication
(10) Pub. No.: US 2023/0240086 A1
(43) Pub. Date: Jul. 27, 2023

(54) SEMICONDUCTOR MEMORY DEVICE AND MANUFACTURING METHOD THEREOF

(71) Applicant: SK hynix Inc., Icheon (KR)

(72) Inventors: Si Jung YOO, Icheon (KR); Tae Hoon KIM, Icheon (KR)

(21) Appl. No.: 17/857,938

(22) Filed: Jul. 5, 2022

(30) Foreign Application Priority Data
Jan. 21, 2022 (KR) 10-2022-0009485

(51) Int. Cl. H01L 27/24; H01L 45/00

(52) U.S. Cl. CPC H01L 27/249; H01L 45/143; H01L 45/1683

(57) ABSTRACT

A semiconductor memory device and a method of manufacturing the semiconductor memory device are provided. The semiconductor memory device includes a plurality of insulating layers spaced apart from each other in a stacking direction, a slit insulating layer passing through the plurality of insulating layers, a plurality of first variable resistance layers alternately disposed with the plurality of insulating layers in the stacking direction, a plurality of conductive lines interposed between the slit insulating layer and the plurality of first variable resistance layers and alternately disposed with the plurality of insulating layers in the stacking direction, a conductive pillar passing through the plurality of insulating layers and the plurality of first variable resistance layers, and a second variable resistance layer surrounding a sidewall of the conductive pillar.

### CROSS-REFERENCE TO RELATED APPLICATION

The present application claims priority under 35 U.S.C. § 119(a) to Korean Patent Application Number 10-2022-0009485, filed on Jan. 21, 2022, which is incorporated herein by reference in its entirety.

### BACKGROUND

### Field of Invention

Various embodiments of the present disclosure generally relate to an electronic device and a manufacturing method thereof, and more particularly, to a semiconductor memory device including a variable resistance layer and a manufacturing method thereof.

### Description of Related Art

An electronic device may include a semiconductor memory device for storing data. The semiconductor memory device may include a memory cell capable of storing two or more logic states. Various techniques for increasing integration density of the memory cell and an operating speed of the memory cell in a low power state have been developed as demand for miniaturization and high performance of the electronic device arises.

Next-generation memory devices such as a phase-change Random Access Memory (PRAM) device, a magnetic RAM (MRAM) device, and a Resistive RAM (RRAM) device have been proposed as semiconductor memory devices capable of increasing integration density and an operating speed in a low power state.

### SUMMARY

According to an embodiment, a semiconductor memory device may include a plurality of insulating layers spaced apart from each other in a stacking direction, a slit insulating layer passing through the plurality of insulating layers, a plurality of first variable resistance layers alternately disposed with the plurality of insulating layers in the stacking direction, a plurality of conductive lines interposed between the slit insulating layer and the plurality of first variable resistance layers and alternately disposed with the plurality of insulating layers in the stacking direction, a conductive pillar passing through the plurality of insulating layers and the plurality of first variable resistance layers, and a second variable resistance layer surrounding a sidewall of the conductive pillar.

According to an embodiment, a method of manufacturing a semiconductor memory device may include forming a stacked structure including a plurality of insulating layers and a plurality of first variable resistance layers that are alternately stacked with each other, forming a hole passing through the stacked structure, forming a second variable resistance layer on a sidewall of the hole, forming a conductive pillar in a region of the hole that is exposed by the second variable resistance layer, forming a slit passing through the stacked structure, forming a plurality of openings by etching a part of each of the plurality of first variable resistance layers, the part being adjacent to the slit, and forming a plurality of conductive lines respectively in the plurality of openings.

### BRIEF DESCRIPTION OF THE DRAWINGS

FIGS. 1A and 1B are schematic diagrams illustrating a semiconductor memory device according to an embodiment of the present disclosure;

FIG. 2 is a schematic perspective view illustrating a semiconductor memory device according to an embodiment of the present disclosure;

FIG. 3 is a cross-sectional diagram of a semiconductor memory device taken along line I-I′ shown in FIG. 2; and

FIGS. 4A, 4B, 4C, 4D, 4E, and 4F are cross-sectional diagrams illustrating a method of manufacturing a semiconductor memory device according to an embodiment of the present disclosure.

### DETAILED DESCRIPTION

The specific structural or functional description disclosed herein is merely illustrative for the purpose of describing embodiments according to the concept of the present disclosure. Embodiments according to the concept of the present disclosure may be implemented in various forms, and should not be construed as limited to the specific embodiments set forth herein.

Hereinafter, the terms such as “first” and “second” may be used to describe various components. However, the components should not be limited by these terms. These terms are used for distinguishing one element from another element and not to suggest a number or order of elements.

Various embodiments of the present disclosure are directed to a semiconductor memory device capable of improving integration density and operational reliability thereof and a method of manufacturing the semiconductor memory device.

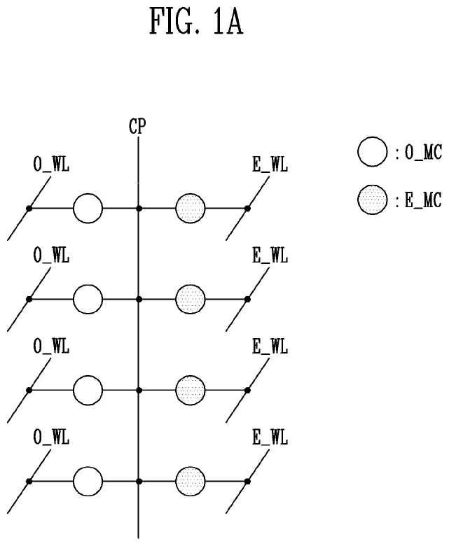

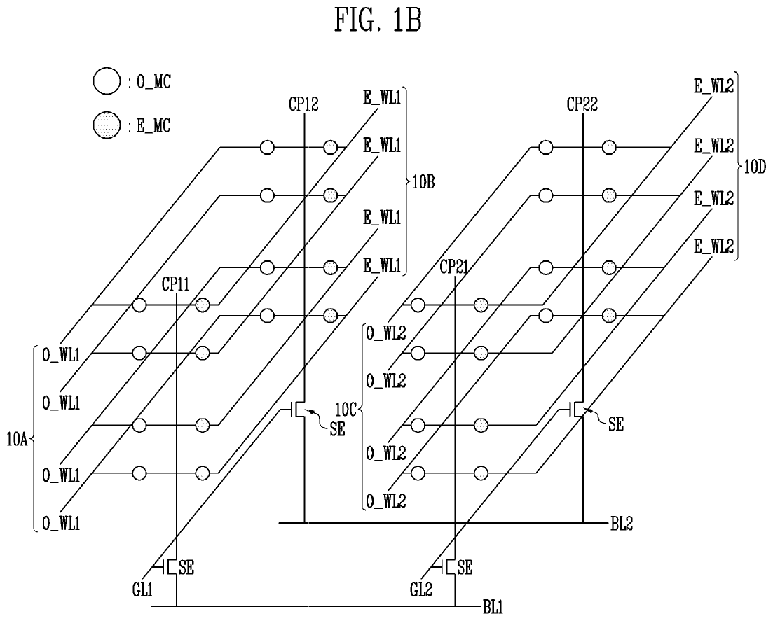

FIGS. 1A and 1B are schematic diagrams illustrating a semiconductor memory device according to an embodiment of the present disclosure. FIG. 1A is a schematic circuit diagram of a memory cell array and FIG. 1B is a schematic circuit diagram of a memory cell array and a bit line connected thereto.

Referring to FIG. 1A, the semiconductor memory device may include a plurality of memory cells O_MC and E_MC disposed at intersections of a conductive pillar CP and a plurality of conductive lines O_WL and E_WL. The conductive pillar CP and the plurality of conductive lines O_WL and E_WL may serve as access lines for accessing the plurality of memory cells O_MC and E_MC. Operating voltages used for a program operation and a read operation on the plurality of memory cells O_MC and E_MC may be applied to the conductive pillar CP and the plurality of conductive lines O_WL and E_WL. The program operation and the read operation may be performed on a memory cell selected, according to the operating voltages that are applied to the conductive pillar CP and the plurality of conductive lines O_WL and E_WL.

According to an embodiment, the conductive pillar CP may be a vertical bit line that is selected in response to a column address and the plurality of conductive lines O_WL and E_WL may be word lines that are selected in response to a row address. Hereinafter, embodiments of the present disclosure in which the conductive pillar CP is the vertical bit line and the plurality of conductive lines O_WL and E_WL are a plurality of word lines will be described. However, embodiments of the present disclosure are not limited thereto. According to another embodiment, the conductive pillar CP may be a vertical word line and the plurality of conductive lines O_WL and E_WL may be a plurality of bit lines.

The plurality of conductive lines O_WL and E_WL may include a plurality of odd word lines O_WL and a plurality of even word lines E_WL. The plurality of memory cells O_MC and E_MC may include a plurality of odd memory cells O_MC connected to the plurality of odd word lines O_WL and the conductive pillar CP and a plurality of even memory cells E_MC connected to the plurality of even word lines E_WL and the conductive pillar CP.

Each of the plurality of memory cells O_MC and E_MC may include a variable resistance material capable of forming both a memory and a select device. When the plurality of memory cells O_MC and E_MC include the variable resistance material capable of forming both the memory and the select device, a structure of a semiconductor memory device may be simplified, manufacturing costs may be reduced, and integration density of the semiconductor memory device may be improved. The variable resistance material capable of forming both the memory and the select device may include a chalcogenide material of which resistance may be changed without a phase change. The chalcogenide material may include germanium (Ge), antimony (Sb), tellurium (Te), arsenic (As), selenium (Se), silicon (Si), indium (In), tin (Sn), sulfur (S), gallium (Ga), or a combination thereof. According to an embodiment, the chalcogenide material may be a binary compound or a multicomponent compound including germanium (Ge) and selenium (Se). Examples of such a compound of germanium (Ge) and selenium (Se) are GeSe, Ge₃Se₇, Ge₄Se₆, and Ge₂Se₃. The chalcogenide material may further include transition metal such as zinc (Zn) or magnesium (Mg).

A distribution of ions in the chalcogenide material of each of the plurality of memory cells O_MC and E_MC may vary depending on polarity of a program pulse applied to each of the plurality of memory cells O_MC and E_MC. According to these characteristics of the chalcogenide material of each of the plurality of memory cells O_MC and E_MC, each of the plurality of memory cells O_MC and E_MC may have a threshold voltage that varies depending on the polarity of the program pulse. For example, when a selected memory cell is programmed using a first program pulse having first polarity, the selected memory cell may have a first threshold voltage. Alternatively, when the selected memory cell is programmed using a second program pulse having second polarity opposite to the first polarity, the selected memory cell may have a second threshold voltage having a different level from that of the first threshold voltage. Absolute value of the first program pulse and absolute value of the second program pulse may be the same or different from each other. A width of the first program pulse and a width of the second program pulse may be the same or different from each other.

A first program state having the first threshold voltage and a second program state having the second threshold voltage may be referred to as a set state and a reset state, respectively. For example, the first threshold voltage may have a lower level than the second threshold voltage. The set state may refer to a first program state having the first threshold voltage which has a relatively low level, and the reset state may refer to a second program state having the second threshold voltage which has a relatively high level. The chalcogenide material may be in an amorphous state when a program pulse, which is set to program a memory cell to the reset state, is applied. And the chalcogenide material may be in an amorphous state when a program pulse, which is set to program a memory cell to the set state, is applied. In other words, the chalcogenide material may provide an amorphous state for the reset state and an amorphous state for the set state.

A read operation for reading data stored in the plurality of memory cells O_MC and E_MC may be performed to identify the data stored in the plurality of memory cells O_MC and E_MC by determining polarity of a program pulse by using polarity of a read pulse. According to an embodiment, a read pulse having first polarity or a read pulse having second polarity may be used in the read operation. When polarity of a program pulse is the same as polarity of a read pulse, a first resistance value may be detected. Alternatively, when the polarity of the program pulse is opposite to the polarity of the read pulse, a second resistance value which is different from the first resistance value may be detected. Accordingly, the polarity of the program pulse may be determined based on a resistance value which is detected when the read pulse is applied and the data stored in the plurality of memory cells O_MC and E_MC may be identified using the determined polarity of the program pulse.

The polarity of the program or read pulse may be determined by a potential difference between a selected conductive pillar and a selected conductive line (e.g., a word line). For example, the first polarity may be positive polarity and the second polarity may be negative polarity. For example, the positive polarity may be defined as polarity in a case where a voltage applied to the selected conductive pillar is greater than a voltage applied to the selected conductive line. The negative polarity may be defined as polarity in a case where a voltage applied to the selected conductive pillar is smaller than a voltage applied to the selected conductive line.

Referring to FIG. 1B, the memory cell array may include the plurality of memory cells O_MC and E_MC described with reference to FIG. 1A. Hereinafter, a detailed description of components already described above with reference to FIG. 1A will be omitted for the sake of brevity.

The plurality of memory cells O_MC and E_MC may be connected to a plurality of conductive pillars CP11, CP12, CP21, and CP22 and a plurality of conductive lines O_WL1, E_WL1, O_WL2, and E_WL2.

The plurality of conductive lines O_WL1, E_WL1, O_WL2, and E_WL2 may include a plurality of first odd word lines O_WL1, a plurality of first even word lines E_WL1, a plurality of second odd word lines O_WL2, and a plurality of second even word lines E_WL2. The plurality of first odd word lines O_WL1 may form a first access group 10A, the plurality of first even word lines E_WL1 may form a second access group 10B, the plurality of second odd word lines O_WL2 may form a third access group 10C, and the plurality of second even word lines E_WL2 may form a fourth access group 10D.

The plurality of conductive pillars CP11, CP12, CP21, and CP22 may include a plurality of first conductive pillars CP11 and CP12 disposed between the first access group 10A and the second access group 10B and a plurality of second conductive pillars CP21 and CP22 disposed between the third access group 10C and the fourth access group 10D.

The plurality of first conductive pillars CP11 and CP12 and the plurality of second conductive pillars CP21 and CP22 may be connected to a plurality of bit lines BL1 and BL2 via a plurality of select devices SE. Operating voltages applied to the plurality of bit lines BL1 and BL2 may be selectively applied to the plurality of first conductive pillars CP11 and CP12 and the plurality of second conductive pillars CP21 and CP22 according to control of the plurality of select devices SE. According to an embodiment, each of the select devices SE may be a transistor configured to transmit an operating voltage of a corresponding bit line to a corresponding conductive pillar according to a gate signal.

For example, the plurality of bit lines BL1 and BL2 may include a first bit line BL1 and a second bit line BL2. The plurality of first conductive pillars CP11 and CP12 may be separated into a first conductive pillar CP11 of a first group which is connected to the first bit line BL1 via the select device SE and a first conductive pillar CP12 of a second group which is connected to the second bit line BL2 via the select device SE. Similarly, the plurality of second conductive pillars CP21 and CP22 may also be separated into a second conductive pillar CP21 of the first group which is connected to the first bit line BL1 via the select device SE and a second conductive pillar CP22 of the second group which is connected to the second bit line BL2 via the select device SE.

The plurality of select devices SE may be connected to a plurality of gate lines GL1 and GL2 each transmitting a gate signal. The plurality of gate lines GL1 and GL2 may include a first gate line GL1 that controls the select devices SE connected to the plurality of first conductive pillars CP11 and CP12 in common and a second gate line GL2 that controls the select devices SE connected to the plurality of second conductive pillars CP21 and CP22 in common.

According to the above-described structure, signals applied to the plurality of conductive pillars CP11, CP12, CP21, and CP22 may be separately controlled according to signals applied to the plurality of gate lines GL1 and GL2 and the plurality of bit lines BL1 and BL2.

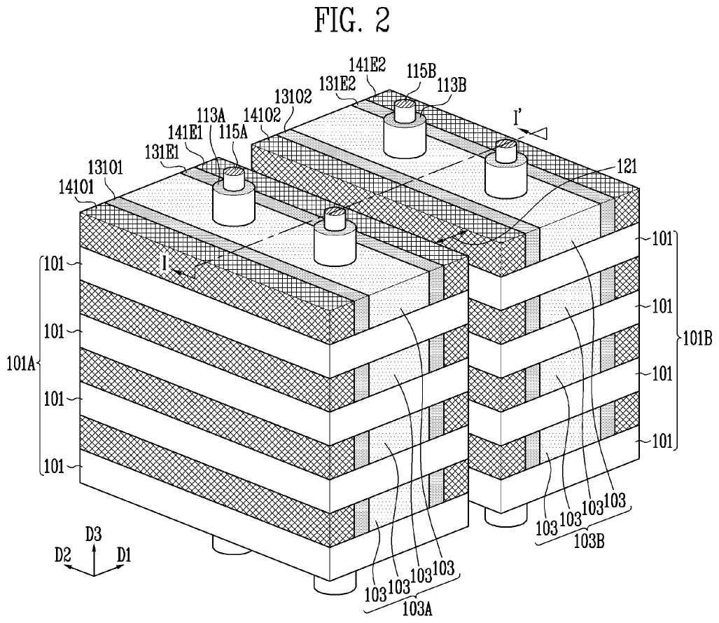

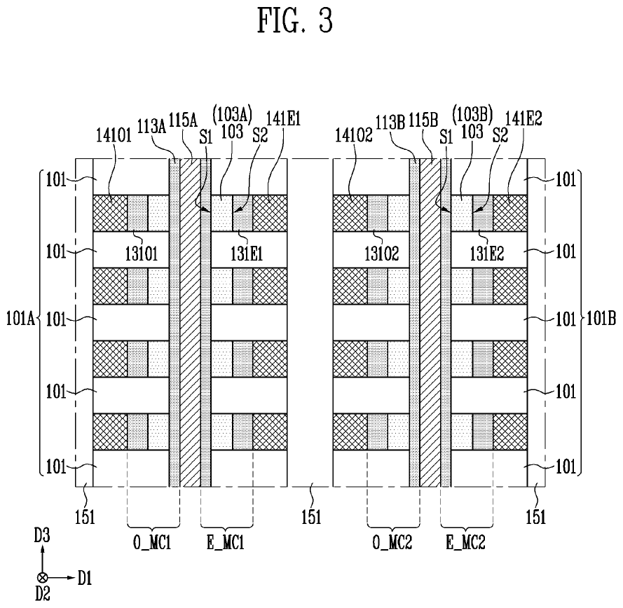

The plurality of memory cells O_MC and E_MC of embodiments shown in FIGS. 1A and 1B may be arranged in three dimensions. Hereinafter, a structure of a three-dimensional memory cell array is described with reference to FIGS. 2 and 3.

FIG. 2 is a schematic perspective view illustrating a semiconductor memory device according to an embodiment of the present disclosure. FIG. 3 is a cross-sectional diagram of the semiconductor memory device taken along line I-I′ shown in FIG. 2.

Referring to FIGS. 2 and 3, the semiconductor memory device may include a plurality of memory cells O_MC1, E_MC1, O_MC2, and E_MC2 that are three-dimensionally arranged. The plurality of memory cells O_MC1, E_MC1, O_MC2, and E_MC2 may be insulated from each other by a plurality of insulating layers 101 and a slit insulating layer 151. The slit insulating layer 151 may be formed in a slit 121. The plurality of insulating layers 101 and the slit insulating layer 151 may include various insulating materials such as an oxide or a nitride.

The plurality of insulating layers 101 may be penetrated by the slit 121. The plurality of insulating layers 101 may be divided into a first mold structure 101A and a second mold structure 101B that neighbor each other with the slit 121 interposed therebetween. The first mold structure 101A and the second mold structure 101B may be spaced apart from each other in a first direction D1 by the slit 121. Each of the first mold structure 101A and the second mold structure 101B may extend in a second direction D2. The plurality of insulating layers 101 of each of the first mold structure 101A and the second mold structure 101B may be stacked to be spaced apart from each other in a third direction D3. The third direction D3 may be regarded as a stacking direction. The first direction D1, the second direction D2, and the third direction D3 may be defined as directions that intersect each other. According to an embodiment, the first direction D1, the second direction D2, and the third direction D3 may be defined as corresponding to an X axis, a Y axis, and a Z axis of an XYZ-coordinate system, respectively.

The plurality of insulating layers 101 may be alternately disposed with a plurality of first variable resistance layers 103 in the third direction D3. The plurality of first variable resistance layers 103 may include a first variable resistance layer 103A of a first group which corresponds to the first mold structure 101A and a first variable resistance layer 103B of a second group which corresponds to the second mold structure 101B.

A plurality of conductive pillars 115A and 115B for accessing the plurality of memory cells O_MC1, E_MC1, O_MC2, and E_MC2 may pass through the plurality of insulating layers 101 and the plurality of first variable resistance layers 103. The plurality of conductive pillars 115A and 115B may include various conductive materials such as metal. For example, the plurality of conductive pillars 115A and 115B may include tungsten (W), a tungsten nitride (WNx), a tungsten silicide (WSix), titanium (Ti), a titanium nitride (TiNx), a titanium silicon nitride (TiSiN), a titanium aluminum nitride (TiAlN), tantalum (Ta), a tantalum nitride (TaN), a tantalum silicon nitride (TaSiN), a tantalum aluminum nitride (TaAlN), carbon (C), silicon carbide (SiC), a silicon carbon nitride (SiCN), copper (Cu), zinc (Zn), nickel (Ni), cobalt (Co), lead (Pb), platinum (Pt), or a combination thereof.

The plurality of conductive pillars 115A and 115B may include a first conductive pillar 115A and a second conductive pillar 115B. The first conductive pillar 115A may be surrounded by the first mold structure 101A and the first variable resistance layer 103A of the first group with a second variable resistance layer 113A, the second variable resistance layer 113A being interposed between the first conductive pillar 115A and the first mold structure 101A and between the first conductive pillar 115A and the first variable resistance layer 103A of the first group. Specifically, the first conductive pillar 115A may be surrounded by a second variable resistance layer 113A, a first portion of the second variable resistance layer 113A may be surrounded by an insulating layer 101 of the first mold structure 101A, and a second portion of the second variable resistance layer 113A may be surrounded by a first variable resistance layer 103A of the first group, the first and second portions of the second variable resistance layer 113A being adjacent to each other in a direction (e.g., the third direction D3) along which the first conductive pillar 115A extends. The second conductive pillar 115B may be surrounded by the second mold structure 101B and the first variable resistance layer 103B of the second group with a second variable resistance layer 113B, the second variable resistance layer 113B being interposed between the second conductive pillar 115B and the second mold structure 101B and between the second conductive pillar 115B and the first variable resistance layer 103B of the second group.

The second variable resistance layer 113A may extend to surround a sidewall of the first conductive pillar 115A and the second variable resistance layer 113B may extend to surround a sidewall of the second conductive pillar 115B. Each of the first variable resistance layers 103 may have a first etched surface S1 that faces a corresponding conductive pillar 115A or 115B. Each of the second variable resistance layers 113A and 113B may contact the first etched surface S1 of a corresponding first variable resistance layer 103A or 103B. The second variable resistance layers 113A and 113B may include the same element as the first variable resistance layers 103 such that an element that is lost at the first etched surface S1 of each of the first variable resistance layers 103 may be compensated. For example, while performing an etching process, the one or more elements (e.g., Ge or Se) of the first variable resistance layer 103 may be lost, leading to relatively small amounts in a portion of the first variable resistance layer 103 including the first etched surface S1. Since the second variable resistance layer 113A or 113B may include these elements in sufficient amounts and contact the first variable resistance layer 103A or 103B at the first etched surface S1, the elements included in the second variable resistance layer 113A or 113B may diffuse into the portion of the first variable resistance layer 103A or 103B including the first etched surface S1 in subsequent manufacturing processes, thereby recovering the amounts of the elements in the portion the first variable resistance layer 103A or 103B.

A plurality of conductive lines 141O1, 141E1, 141O2, and 141E2 for accessing the plurality of memory cells O_MC1, E_MC1, O_MC2, and E_MC2 may be interposed between the slit insulating layer 151 and the plurality of first variable resistance layers 103. The plurality of conductive lines 141O1, 141E1, 141O2, and 141E2 may include various conductive materials such as metal. For example, the plurality of conductive lines 141O1, 141E1, 141O2, and 141E2 may include tungsten (W), a tungsten nitride (WNx), a tungsten silicide (WSix), titanium (Ti), a titanium nitride (TiNx), a titanium silicon nitride (TiSiN), a titanium aluminum nitride (TiAlN), tantalum (Ta), a tantalum nitride (TaN), a tantalum silicon nitride (TaSiN), a tantalum aluminum nitride (TaAlN), carbon (C), silicon carbide (SiC), a silicon carbon nitride (SiCN), copper (Cu), zinc (Zn), nickel (Ni), cobalt (Co), lead (Pb), platinum (Pt), or a combination thereof.

The plurality of conductive lines 141O1, 141E1, 141O2, and 141E2 may include a plurality of first odd conductive lines 141O1, a plurality of first even conductive lines 141E1, a plurality of second odd conductive lines 141O2, and a plurality of second even conductive lines 141E2. The plurality of first odd conductive lines 141O1, the plurality of first even conductive lines 141E1, the plurality of second odd conductive lines 141O2, and the plurality of second even conductive lines 141E2 may serve as the plurality of first odd word lines O_WL1, the plurality of first even word lines E_WL1, the plurality of second odd word lines O_WL2, and the plurality of second even word lines E_WL2 described above with reference to FIG. 1B.

The plurality of first odd conductive lines 141O1 may be disposed at one side of the first variable resistance layer 103A of the first group and may be alternately disposed with the plurality of insulating layers 101 of the first mold structure 101A in the third direction D3. The plurality of first even conductive lines 141E1 may be disposed at the other side of the first variable resistance layer 103A of the first group and may be alternately disposed with the plurality of insulating layers 101 of the first mold structure 101A in the third direction D3. The plurality of second odd conductive lines 141O2 may be disposed at one side of the first variable resistance layer 103B of the second group and may be alternately disposed with the plurality of insulating layers 101 of the second mold structure 101B in the third direction D3. The plurality of second even conductive lines 141E2 may be disposed at the other side of the first variable resistance layer 103B of the second group and may be alternately disposed with the plurality of insulating layers 101 of the second mold structure 101B in the third direction D3.

The semiconductor memory device may further include a plurality of third variable resistance layers 131O1, 131E1, 131O2, and 131E2 interposed between the plurality of first variable resistance layers 103 and the plurality of conductive lines 141O1, 141E1, 141O2, and 141E2. For example, each of the third variable resistance layers 131O1, 131E1, 131O2, and 131E2 may be interposed between a corresponding one of the plurality of first variable resistance layers 103 and a corresponding one of the plurality of conductive lines 141O1, 141E1, 141O2, and 141E2. Each of the first variable resistance layers 103 may have a second etched surface S2 that faces a corresponding conductive line 141O1, 141E1, 141O2, or 141E2. Each of the plurality of third variable resistance layers 131O1, 131E1, 131O2, and 131E2 may contact the second etched surface S2 of a corresponding first variable resistance layer 103. The plurality of third variable resistance layers 131O1, 131E1, 131O2, and 131E2 may include the same element as the first variable resistance layers 103 such that an element that is lost at the second etched surface S2 of each of the first variable resistance layers 103 may be compensated. For example, while performing an etching process, the one or more elements (e.g., Ge or Se) of the first variable resistance layer 103 may be lost, leading to relatively small amounts in a portion of the first variable resistance layer 103 including the second etched surface S2. Since the third variable resistance layer 131O1, 131E1, 131O2, or 131E2 may include these elements in sufficient amounts and contact the first variable resistance layer 103A or 103B at the second etched surface S2, the elements included in the third variable resistance layer 131O1, 131E1, 131O2, or 131E2 may diffuse into the portion of the first variable resistance layer 103A or 103B including the second etched surface S2 in subsequent manufacturing processes, thereby recovering the amounts of the elements in the portion of the first variable resistance layer 103A or 103B.

The plurality of third variable resistance layers 131O1, 131E1, 131O2, and 131E2 may include a plurality of third variable resistance layers 131O1 of a first odd group, a plurality of third variable resistance layers 131E1 of a first even group, a plurality of third variable resistance layers 131O2 of a second odd group, and a plurality of third variable resistance layers 131E2 of a second even group. The plurality of third variable resistance layers 131O1 of the first odd group may be alternately disposed with the plurality of insulating layers 101 of the first mold structure 101A in the third direction D3, and each of the plurality of third variable resistance layers 131O1 may be interposed between the first odd conductive line 141O1 and the first variable resistance layer 103A of the first group that correspond to each of the plurality of third variable resistance layers 131O1. The plurality of third variable resistance layers 131E1 of the first even group may be alternately disposed with the plurality of insulating layers 101 of the first mold structure 101A in the third direction D3, and each of the plurality of third variable resistance layers 131E1 may be interposed between the first even conductive line 141E1 and the first variable resistance layer 103A of the first group that correspond to each of the plurality of third variable resistance layers 131E1. The plurality of third variable resistance layers 131O2 of the second odd group may be alternately disposed with the plurality of insulating layers 101 of the second mold structure 101B in the third direction D3, and each of the plurality of third variable resistance layers 131O2 may be interposed between the second odd conductive line 141O2 and the first variable resistance layer 103B of the second group that correspond to each of the plurality of third variable resistance layers 131O2. The plurality of third variable resistance layers 131E2 of the second even group may be alternately disposed with the plurality of insulating layers 101 of the second mold structure 101B in the third direction D3 and each of the plurality of third variable resistance layers 131E2 may be interposed between the second even conductive line 141E2 and the first variable resistance layer 103B of the second group that correspond to each of the plurality of third variable resistance layers 131E2.

As described above with reference to FIG. 1A, the plurality of memory cells O_MC1, E_MC1, O_MC2, and E_MC2 may implement a program state of a set state or a reset state by using a threshold voltage that varies depending on polarity of a program pulse applied to the plurality of first variable resistance layers 103. As described above with reference to FIG. 1A, a read operation on a selected memory cell among the plurality of memory cells O_MC1, E_MC1, O_MC2, and E_MC2 may be performed to identify data stored in the selected memory cell by determining the polarity of the program pulse by using polarity of a read pulse.

The plurality of memory cells O_MC1, E_MC1, O_MC2, and E_MC2 may include a plurality of first odd memory cells O_MC1, a plurality of first even memory cells E_MC1, a plurality of second odd memory cells O_MC2, and a plurality of second even memory cells E_MC2.

The plurality of first odd memory cells O_MC1 and the plurality of first even memory cells E_MC1 may be controlled in common by the first conductive pillar 115A. Each of the plurality of first odd memory cells O_MC1 may include a part of the first variable resistance layer 103A of the first group disposed at an intersection of the first odd conductive line 141O1 corresponding to each of the plurality of first odd memory cells O_MC1 and the first conductive pillar 115A. Each of the plurality of first odd memory cells O_MC1 may further include a part of the second variable resistance layer 113A disposed at an intersection of the first odd conductive line 141O1 corresponding to each of the plurality of first odd memory cells O_MC1 and the first conductive pillar 115A, or the third variable resistance layer 131O1 of the first odd group corresponding to each of the plurality of first odd memory cells O_MC1, or both. Each of the plurality of first even memory cells E_MC1 may include another part of the first variable resistance layer 103A of the first group disposed at an intersection of the first even conductive line 141E1 corresponding to each of the plurality of first even memory cells E_MC1 and the first conductive pillar 115A. Each of the plurality of first even memory cells E_MC1 may further include another part of the second variable resistance layer 113A disposed at an intersection of the first even conductive line 141E1 corresponding to each of the plurality of first even memory cells E_MC1 and the first conductive pillar 115A, or the third variable resistance layer 131E1 of the first even group corresponding to each of the plurality of first even memory cells E_MC1, or both.

The plurality of second odd memory cells O_MC2 and the plurality of second even memory cells E_MC2 may be controlled in common by the second conductive pillar 115B. Each of the plurality of second odd memory cells O_MC2 may include a part of the first variable resistance layer 103B of the second group disposed at an intersection of the second odd conductive line 141O2 corresponding to each of the plurality of second odd memory cells O_MC2 and the second conductive pillar 115B. Each of the plurality of second odd memory cells O_MC2 may further include a part of the second variable resistance layer 113B disposed at an intersection of the second odd conductive line 141O2 corresponding to each of the plurality of second odd memory cells O_MC2 and the second conductive pillar 115B, or the third variable resistance layer 131O2 of the second odd group corresponding to each of the plurality of second odd memory cells O_MC2, or both. Each of the plurality of second even memory cells E_MC2 may include another part of the first variable resistance layer 103B of the second group disposed at an intersection of the second even conductive line 141E2 corresponding to each of the plurality of second even memory cells E_MC2 and the second conductive pillar 115B. Each of the plurality of second even memory cells E_MC2 may further include another part of the second variable resistance layer 113B disposed at an intersection of the second even conductive line 141E2 corresponding to each of the plurality of second even memory cells E_MC2 and the second conductive pillar 115B, or the third variable resistance layer 131E2 of the second even group corresponding to each of the plurality of second even memory cells E_MC2, or both.

The first variable resistance layer 103A of the first group, the first variable resistance layer 103B of the second group, the second variable resistance layers 113A and 113B, and the third variable resistance layers 131O1, 131E1, 131O2, and 131E2 that form the plurality of memory cells O_MC1, E_MC1, O_MC2, and E_MC2 may have threshold voltages that vary depending on polarity of a program pulse and may include a chalcogenide material of which resistance may be changed without a phase change as described above with reference to FIG. 1A. According to an embodiment, each of the first variable resistance layer 103A of the first group, the first variable layer 103B of the second group, the second variable resistance layers 113A and 113B, and the third variable resistance layers 131O1, 131E1, 131O2, and 131E2 may include a binary compound or a multicomponent compound including germanium (Ge) and selenium (Se). Each of the first variable resistance layer 103A of the first group, the first variable resistance layer 103B of the second group, the second variable resistance layers 113A and 113B, and the third variable resistance layers 131O1, 131E1, 131O2, and 131E2 may further include transition metal such as zinc (Zn) or magnesium (Mg).

Element abundance of each of the second variable resistance layers 113A and 113B and the third variable resistance layers 131O1, 131E1, 131O2, and 131E2 may vary depending on a temperature applied during a process of manufacturing the semiconductor memory device after the second variable resistance layers 113A and 113B and the third variable resistance layers 131O1, 131E1, 131O2, and 131E2 are formed.

Each of the second variable resistance layers 113A and 113B and the third variable resistance layers 131O1, 131E1, 131O2, and 131E2 may have substantially the same composition as a first variable resistance layer corresponding thereto or may include one or more elements that constitute the corresponding first variable resistance layer. According to an embodiment, each of the second variable resistance layers 113A and 113B and the third variable resistance layers 131O1, 131E1, 131O2, and 131E2 may include a chalcogenide material having substantially the same composition as a chalcogenide material of the corresponding first variable resistance layer. For example, content of each of elements (e.g., germanium (Ge) and selenium (Se)) in a chalcogenide material of each of the second variable resistance layers 113A and 113B and the third variable resistance layers 131O1, 131E1, 131O2, and 131E2 may be in a range from 95% to 105%, 97% to 103%, 99% to 101%, 99.5% to 100.5%, or 99.7% to 100.3% of content of the same element in a chalcogenide material of the corresponding first variable resistance layer. According to another embodiment, each of the second variable resistance layers 113A and 113B and the third variable resistance layers 131O1, 131E1, 131O2, and 131E2 may include a chalcogenide material of which content of at least one of germanium (Ge) and selenium (Se) is higher than that of a chalcogenide material of the corresponding first variable resistance layer. In other words, each of the second variable resistance layers 113A and 113B and the third variable resistance layers 131O1, 131E1, 131O2, and 131E2 may include a chalcogenide material of which content of germanium (Ge) is higher than that of a chalcogenide material of the corresponding first variable resistance layer, or content of selenium (Se) is higher than that of a chalcogenide material of the corresponding first variable resistance layer, or both.

Although not illustrated in FIGS. 2 and 3, a barrier insulating layer may be disposed between each of the plurality of memory cells O_MC1, E_MC1, O_MC2, and E_MC2 and a conductive pillar corresponding thereto or between each of the plurality of memory cells O_MC1, E_MC1, O_MC2, and E_MC2 and a conductive line corresponding thereto.

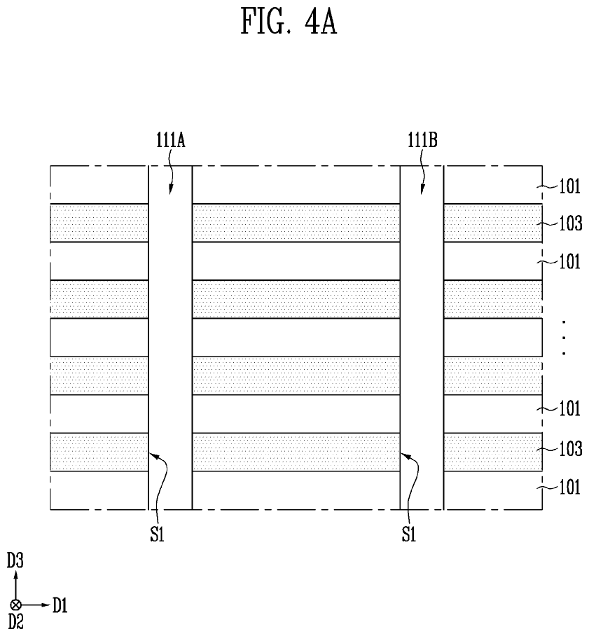

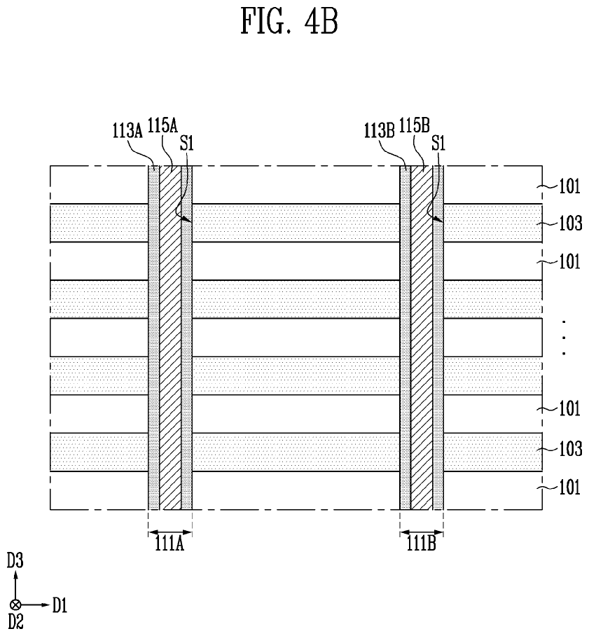

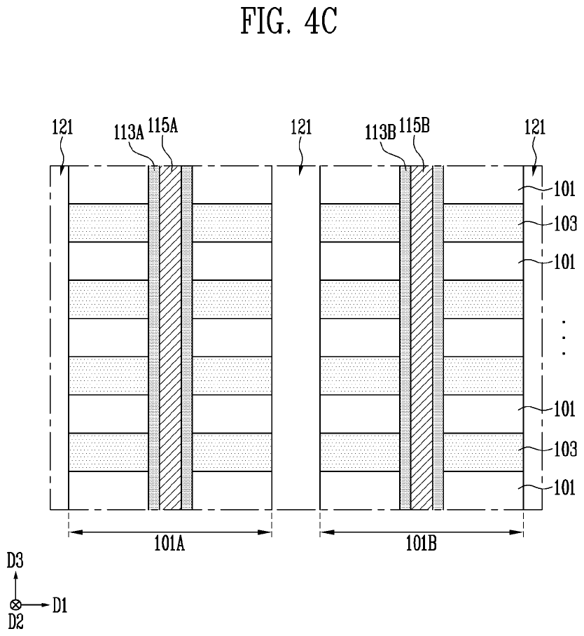

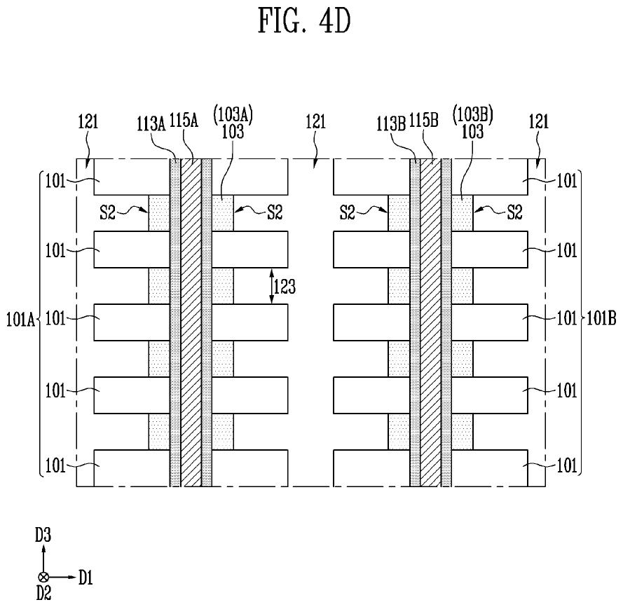

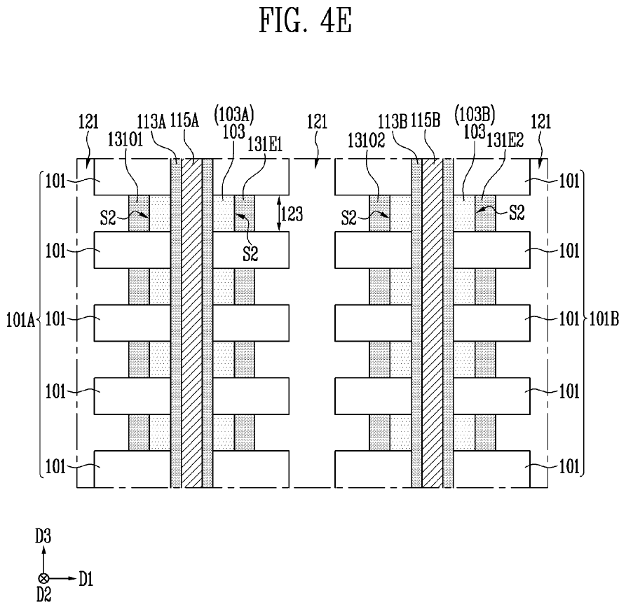

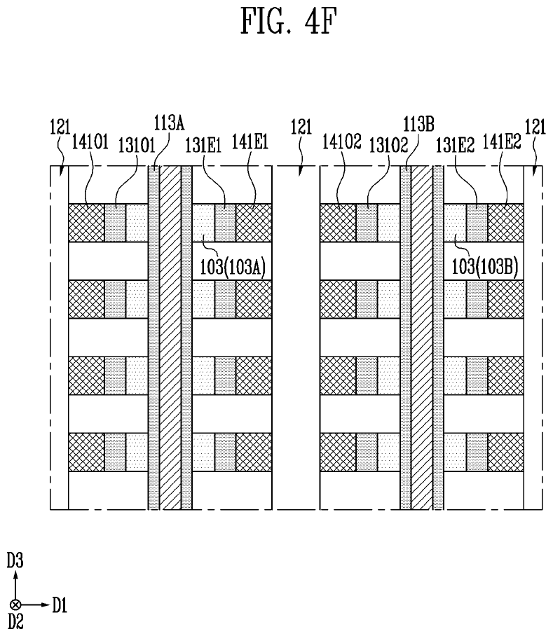

FIGS. 4A, 4B, 4C, 4D, 4E, and 4F are cross-sectional diagrams illustrating a method of manufacturing a semiconductor memory device according to an embodiment of the present disclosure. FIGS. 4A to 4F illustrate a method of manufacturing the semiconductor memory device shown in FIGS. 2 and 3, according to an embodiment. Hereinafter, detailed descriptions of some components already shown in FIGS. 2 and 3 may be omitted for the sake of brevity.

Referring to FIG. 4A, a stacked structure in which the plurality of insulating layers 101 and the plurality of first variable resistance layers 103 are alternately stacked in the third direction D3 may be formed. The plurality of insulating layers 101 and the plurality of first variable resistance layers 103 may be formed over a substrate (not shown). Accordingly, the plurality of insulating layers 101 and the plurality of first variable resistance layers 103 may be deposited by a physical vapor deposition (PVD) method in which step coverage is relatively low. A composition ratio of a material layer deposited by the PVD method may easily be changed than a chemical vapor deposition (CVD) method and an atomic layer deposition (ALD) method. Accordingly, when the plurality of first variable resistance layers 103 are deposited by the PVD method, composition ratios of the plurality of first variable resistance layers 103 may be differently controlled. That is, in an embodiment, a PVD method may be used to facilitate control of composition ratios in the plurality of first variable resistance layers 103 compared to other deposition methods such as a CVD method and an ALD method. As described above with reference to FIGS. 2 and 3, the plurality of first variable resistance layers 103 may include a binary compound or a multicomponent compound including germanium (Ge) and selenium (Se). However, embodiments of the present disclosure are not limited to the embodiment in which the plurality of first variable resistance layers 103 are deposited by the PVD method, and deposition methods of the plurality of first variable resistance layers 103 may vary according to embodiments.

Subsequently, a plurality of holes 111A and 111B passing through the stacked structure may be formed by etching the plurality of insulating layers 101 and the plurality of first variable resistance layers 103. The plurality of first variable resistance layers 103 may include the plurality of first etched surfaces S1 defining a sidewall of each of the plurality of holes 111A and 111B. Elements that constitute the plurality of first variable resistance layers 103 may be lost at the plurality of first etched surfaces S1 by an etching material during an etching process for forming the plurality of holes 111A and 111B. According to an embodiment, germanium (Ge), or selenium (Se), or both that constitute each of the plurality of first variable resistance layers 103 may be lost at each of the plurality of first etched surfaces S1. In other words, when the plurality of first variable resistance layers 103 are etched, one or more elements (e.g., Ge and/or Se) may be lost, leading to relatively low contents of these elements in portions of the plurality of the first variable resistance layers 103 including the plurality of first etched surfaces S1.

Referring to FIG. 4B, the plurality of second variable resistance layers 113A and 113B may be formed on the sidewalls of the plurality of holes 111A and 111B, respectively. The plurality of second variable resistance layers 113A and 113B may be formed by a deposition method in which step coverage is relatively high such as an atomic layer deposition (ALD) method. The plurality of second variable resistance layers 113A and 113B may include a binary compound or a multicomponent compound including germanium (Ge) and selenium (Se). Each of the plurality of second variable resistance layers 113A and 113B may include a chalcogenide material in which content of at least one of germanium (Ge) and selenium (Se) is higher than that in a chalcogenide material of each the plurality of first variable resistance layers 103. For example, each of the plurality of first variable resistance layers 103 may include GeSe and each of the plurality of second variable resistance layers 113A and 113B may include Ge₂Se.

The plurality of second variable resistance layers 113A and 113B may contact the plurality of first etched surfaces S1 of the plurality of first variable resistance layers 103. Accordingly, elements that are lost at the plurality of first etched surfaces S1 may be compensated through the plurality of second variable resistance layers 113A and 113B.

Subsequently, the plurality of conductive pillars 115A and 115B may be formed in a plurality of regions (e.g., central regions) of the plurality of holes 111A and 111B that are exposed by the plurality of second variable resistance layers 113A and 113B. The plurality of holes 111A and 111B may include a first hole 111A and a second hole 111B that are spaced apart from each other in the first direction D1. The plurality of conductive pillars 115A and 115B may include a first conductive pillar 115A in the first hole 111A and a second conductive pillar 115B in the second hole 111B.

Referring to FIG. 4C, one or more slits 121 passing through the stacked structure of the plurality of insulating layers 101 and the plurality of first variable resistance layers 103 may be formed. The slit 121 may extend in the second direction D2. The plurality of insulating layers 101 may be divided into the first mold structure 101A and the second mold structure 101B by the slit 121.

Referring to FIG. 4D, each of a plurality of openings 123 may be formed by etching a part of each of the plurality of first variable resistance layers 103 that is adjacent to the slit 121. Remaining parts of the plurality of first variable resistance layers 103 may respectively include the plurality of second etched surfaces S2 that face the slit 121. The remaining parts of the plurality of first variable resistance layers 103 may include the first variable resistance layer 103A of the first group which surrounds the first conductive pillar 115A and the first variable resistance layer 103B of the second group which surrounds the second conductive pillar 115B.

The plurality of openings 123 may be formed between the plurality of insulating layers 101 of the first mold structure 101A which neighbor in the third direction D3 and between the plurality of insulating layers 101 of the second mold structure 101B which neighbor in the third direction D3. The plurality of openings 123 may be isolated from each other in the first direction D1 by the plurality of first variable resistance layers 103.

Elements that constitute the plurality of first variable resistance layers 103 may be lost at the plurality of second etched surfaces S2 by an etching material during an etching process for forming the plurality of openings 123. According to an embodiment, at least one of germanium (Ge) and selenium (Se) that constitute each of the plurality of first variable resistance layers 103 may be lost at each of the plurality of second etched surfaces S2. In other words, when the plurality of first variable resistance layers 103 in FIG. 4C are etched, one or more elements (e.g., Ge and/or Se) may be lost, leading to relatively low contents of these elements in portions of the plurality of first variable resistance layers 103 including the plurality of second etched surfaces S2.

Referring to FIG. 4E, the plurality of third variable resistance layers 131O1, 131E1, 131O2, and 131E2 may be formed in the plurality of openings 123. The plurality of third variable resistance layers 131O1, 131E1, 131O2, and 131E2 may include a binary compound or a multicomponent compound including germanium (Ge) and selenium (Se). Each of the plurality of third variable resistance layers 131O1, 131E1, 131O2, and 131E2 may include a chalcogenide material in which content of at least one of germanium (Ge) and selenium (Se) is higher than that in a chalcogenide material of each of the plurality of first variable resistance layers 103. For example, each of the plurality of first variable resistance layers 103 may include GeSe, and each of the plurality of third variable resistance layers 131O1, 131E1, 131O2, and 131E2 may include Ge₂Se.

The plurality of third variable resistance layers 131O1, 131E1, 131O2, and 131E2 may contact the plurality of second etched surfaces S2 of the plurality of first variable resistance layers 103. Accordingly, elements that are lost at the plurality of second etched surfaces S2 may be compensated through the plurality of third variable resistance layers 131O1, 131E1, 131O2, and 131E2.

The plurality of third variable resistance layers 131O1, 131E1, 131O2, and 131E2 may be formed by an atomic layer deposition (ALD) method using the plurality of first variable resistance layers 103 as seed layers. Accordingly, the plurality of third variable resistance layers 131O1, 131E1, 131O2, and 131E2 may be selectively deposited on the plurality of second etched surfaces S2 of the plurality of first variable resistance layers 103.

The plurality of third variable resistance layers 131O1, 131E1, 131O2, and 131E2 may include the third variable resistance layers 131O1 of the first odd group, the third variable resistance layers 131E1 of the first even group, the third variable resistance layers 131O2 of the second odd group, and the third variable resistance layers 131E2 of the second even group. The third variable resistance layers 131O1 of the first odd group and the third variable resistance layers 131E1 of the first even group may be respectively disposed in openings that are isolated by the first variable resistance layer 103A of the first group among the plurality of openings 123. The third variable resistance layers 131O2 of the second odd group and the third variable resistance layers 131E2 of the second even group may be respectively disposed in openings that are isolated by the first variable resistance layer 103B of the second group among the plurality of openings 123. A part of each of the plurality of openings 123 may not be filled with the plurality of third variable resistance layers 131O1, 131E1, 131O2, and 131E2, and may remain as an empty space between a pair of the insulating layers 101 that neighbor each other in the third direction D3.

Referring to FIG. 4F, the plurality of conductive lines 141O1, 141E1, 141O2, and 141E2 may be formed in the parts of the plurality of openings 123 that remain as the empty spaces shown in FIG. 4E, respectively. The slit 121 may be filled with the slit insulating layer 151 as shown in FIG. 3, after the plurality of conductive lines 141O1, 141E1, 141O2, and 141E2 are formed. Subsequently, processes for forming upper wires (not shown) may be performed. Process temperatures may vary depending on a property of matter for the upper wires during the processes for forming the upper wires. According to an embodiment, a process temperature may be within a range capable of maintaining a state where element abundance of at least one of germanium (Ge) and selenium (Se) in each of the plurality of second variable resistance layers 113A and 113B and the plurality of third variable resistance layers 131O1, 131E1, 131O2, and 131E2 is higher than that in each of the plurality of first variable resistance layers 103 during the processes for forming the upper wires. Specifically, when a process temperature may be in a relatively low range, germanium (Ge), or selenium (Se), or both in the plurality of second variable resistance layers 113A and 113B and the plurality of third variable resistance layers 131O1, 131E1, 131O2, and 131E2 may not sufficiently diffuse into the plurality of first variable resistance layers 103 during the processes for forming the upper wires. As a result, after the processes have been performed, content of germanium (Ge), or content of selenium (Se), or both in the plurality of second variable resistance layers 113A and 113B and the plurality of third variable resistance layers 131O1, 131E1, 131O2, and 131E2 may remain higher than those in the plurality of first variable resistance layers 103. According to another embodiment, a process temperature may be within a range capable of uniformizing element abundance of germanium (Ge) and selenium (Se) in the plurality of second variable resistance layers 113A and 113B and the plurality of third variable resistance layers 131O1, 131E1, 131O2, and 131E2 and that in the plurality of first variable resistance layers 103 during the processes for forming the upper wires. Specifically, when a process temperature may be in a relatively high range, germanium (Ge), or selenium (Se), or both in the plurality of second variable resistance layers 113A and 113B and the plurality of third variable resistance layers 131O1, 131E1, 131O2, and 131E2 may sufficiently diffuse into the plurality of first variable resistance layers 103 during the processes for forming the upper wires. As a result, after the processes have been performed, content of germanium (Ge), or content of selenium (Se), or both in the plurality of second variable resistance layers 113A and 113B and the plurality of third variable resistance layers 131O1, 131E1, 131O2, and 131E2 may be substantially the same as those in the plurality of first variable resistance layers 103.

According to embodiments of the present disclosure, three-dimensionally arranged memory cells may be provided by disposing a variable resistance layer at an intersection of each of a plurality of conductive lines that are alternately stacked with a plurality of insulating layers and a conductive pillar that passes through the plurality of insulating layers, thereby increasing integration density of a semiconductor memory device.

According to embodiments of the present disclosure, damage caused by etching the variable resistance layer of the memory cells may be compensated, thereby increasing operational reliability of the semiconductor memory device.

What is claimed is:

1. A semiconductor memory device, comprising:
a plurality of insulating layers spaced apart from each other in a stacking direction;
a slit insulating layer passing through the plurality of insulating layers;
a plurality of first variable resistance layers alternately disposed with the plurality of insulating layers in the stacking direction;
a plurality of conductive lines interposed between the slit insulating layer and the plurality of first variable resistance layers and alternately disposed with the plurality of insulating layers in the stacking direction;
a conductive pillar passing through the plurality of insulating layers and the plurality of first variable resistance layers; and
a second variable resistance layer surrounding a sidewall of the conductive pillar,
wherein the plurality of first variable resistance layers and the second variable resistance layer include a material of which threshold voltage varies depending on polarity of a program pulse.

2. The semiconductor memory device of claim 1, wherein each of the plurality of first variable resistance layers includes a first etched surface facing the conductive pillar.

3. The semiconductor memory device of claim 1, wherein the plurality of first variable resistance layers include a chalcogenide material having substantially the same composition as a chalcogenide material of the second variable resistance layer.

4. The semiconductor memory device of claim 1, wherein the second variable resistance layer includes one or more elements that constitute each of the plurality of first variable resistance layers.

5. The semiconductor memory device of claim 1, wherein each of the plurality of first variable resistance layers and the second variable resistance layer include germanium (Ge) and selenium (Se).

6. The semiconductor memory device of claim 5, wherein the second variable resistance layer includes a material of which content of at least one of germanium (Ge) and selenium (Se) is higher than content of at least one of germanium (Ge) and selenium (Se) of a material in each of the plurality of first variable resistance layers.

7. The semiconductor memory device of claim 1, further comprising a plurality of third variable resistance layers alternately disposed with the plurality of insulating layers in the stacking direction and interposed between the plurality of first variable resistance layers and the plurality of conductive lines.

8. The semiconductor memory device of claim 7, wherein each of the plurality of first variable resistance layers includes a second etched surface facing a corresponding conductive line among the plurality of conductive lines.

9. The semiconductor memory device of claim 7, wherein the plurality of third variable resistance layers include a material of which threshold voltage varies depending on the polarity of the program pulse.

10. The semiconductor memory device of claim 7, wherein the plurality of first variable resistance layers may include a chalcogenide material having substantially the same composition as a chalcogenide material of the plurality of third variable resistance layers.

11. The semiconductor memory device of claim 7, wherein each of the plurality of third variable resistance layers includes one or more elements that constitute each of the plurality of first variable resistance layers.

12. The semiconductor memory device of claim 7, wherein each of the plurality of first variable resistance layers and each of the plurality of third variable resistance layers include germanium (Ge) and selenium (Se).

13. The semiconductor memory device of claim 12, wherein each of the plurality of third variable resistance layers includes a material of which content of at least one of germanium (Ge) and selenium (Se) is higher than content of at least one of germanium (Ge) and selenium (Se) of a material in each of the plurality of first variable resistance layers.

14. A method of manufacturing a semiconductor memory device, the method comprising:
forming a stacked structure including a plurality of insulating layers and a plurality of first variable resistance layers that are alternately stacked with each other;
forming a hole passing through the stacked structure;
forming a second variable resistance layer on a sidewall of the hole;
forming a conductive pillar in a region of the hole that is exposed by the second variable resistance layer;
forming a slit passing through the stacked structure;
forming a plurality of openings by etching a part of each of the plurality of first variable resistance layers, the part being adjacent to the slit; and
forming a plurality of conductive lines respectively in the plurality of openings.

15. The method of claim 14, wherein the second variable resistance layer contacts the plurality of first variable resistance layers.

16. The method of claim 14, wherein each of the plurality of first variable resistance layers includes germanium (Ge) and selenium (Se), and
wherein the second variable resistance layer includes a material of which content of at least one of germanium (Ge) and selenium (Se) is higher than content of at least one of germanium (Ge) and selenium (Se) of a material in each of the plurality of first variable resistance layers, when the second variable resistance layer is formed.

17. The method of claim 14, further comprising forming a plurality of third variable resistance layers respectively in the plurality of openings,
wherein the plurality of conductive lines are formed respectively in the plurality of openings after forming the plurality of third variable resistance layers.

18. The method of claim 17, wherein the plurality of third variable resistance layers respectively contact the plurality of first variable resistance layers.

19. The method of claim 17, wherein each of the plurality of first variable resistance layers includes germanium (Ge) and selenium (Se), and
wherein the plurality of third variable resistance layers include a material of which content of at least one of germanium (Ge) and selenium (Se) is higher than content of at least one of germanium (Ge) and selenium (Se) of a material in each of the plurality of first variable resistance layers, when the plurality of third variable resistance layers are formed.
